(19) United States
(12) Patent Application Publication
(10) Pub. No.: US 2015/0303318 A1
(43) Pub. Date: Oct. 22, 2015

(54) COMPOSITION FOR FORMING PASSIVATION FILM, SEMICONDUCTOR SUBSTRATE PROVIDED WITH PASSIVATION FILM AND PRODUCTION METHOD THEREFOR, AND PHOTOVOLTAIC CELL ELEMENT AND PRODUCTION METHOD THEREFOR

(71) Applicant: Hitachi Chemical Company, Ltd., Tokyo (JP)

(72) Inventors: Tooru Tanaka, Ibaraki (JP); Akihiro Orita, Ibaraki (JP); Takeshi Nojiri, Ibaraki (JP); Masato Yoshida, Ibaraki (JP)

(21) Appl. No.: 14/370,659

(22) PCT Filed: Dec. 28, 2012
(86) PCT No.: PCT/JP2012/084159

§ 371 Date: Jul. 3, 2014

(30) Foreign Application Priority Data
Jan. 6, 2012 (JP) 2012-001641

(51) Int. Cl. H01L 31/0216; H01L 31/18; H01L 31/0224

(52) U.S. Cl. CPC H01L 31/02167; H01L 31/022433; H01L 31/1804; H01L 31/1868

(57) ABSTRACT

The invention provides a composition for forming a passivation film, including: an organic aluminum compound represented by General Formula (I); and a resin, wherein R¹'s each independently represent an alkyl group having 1 to 8 carbon atoms; n represents an integer of from 0 to 3; X² and X³ each independently represent an oxygen atom or a methylene group; R², R³ and R⁴ each independently represent a hydrogen atom or an alkyl group having 1 to 8 carbon atoms.

### TECHNICAL FIELD

The present invention relates to a composition for forming a passivation film, a semiconductor substrate provided with a passivation film and a production method therefor as well as a photovoltaic cell element and a production method therefor.

### BACKGROUND ART

Conventional processes for producing a silicon photovoltaic cell element will be described.

A p-type silicon substrate with a textured light-receiving surface for attaining higher efficiency by promoting a light trapping effect is prepared, and then is treated in a mixed gas atmosphere of phosphorus oxychloride (POCl₃), nitrogen, and oxygen at a temperature from 800° C. to 900° C. for several tens of minutes to form uniformly an n-type diffusion layer. By this conventional method, since phosphorus is diffused using a mixed gas, the n-type diffusion layer is formed not only on the light-receiving surface but also on side surfaces and a back surface. Therefore, side etching is performed in order to remove the n-type diffusion layer on the side surfaces. Further, since the n-type diffusion layer on the back surface has to be converted to a p⁺-type diffusion layer, an aluminum paste is coated all over the back surface and sintered to form an aluminum electrode, whereby the n-type diffusion layer is converted to a p⁺-type diffusion layer and at the same time an ohmic contact is established.

However, the aluminum electrode formed from the aluminum paste has a low electric conductivity. Therefore, the aluminum electrode formed on the entire back surface should ordinarily have a thickness of from about 10 μm to 20 μm after sintering in order to lower the sheet resistance. Moreover, since silicon and aluminum are quite different in coefficient of thermal expansion, a large internal stress is generated in a silicon substrate during steps of sintering and cooling, which may give damages in a crystal grain boundary, increase crystal defects, or cause a warp.

To eliminate the above drawback, there is a method in which the coating amount of an aluminum paste is decreased so as to reduce the thickness of a back surface electrode layer. However, when the coating amount of an aluminum paste is decreased, the amount of aluminum diffused from a surface of a p-type silicon semiconductor substrate inward becomes insufficient. As a result, there arises another drawback that a desired Back Surface Field (BSF) effect (an effect of improving the collection efficiency of a generated carrier owing to the presence of a p⁺-type diffusion layer) cannot be achieved and the properties of a photovoltaic cell are impaired.

In this connection, a point contact technique in which an aluminum paste is applied onto a part of a silicon substrate surface to partly form a p⁺ layer and an aluminum electrode has been proposed (e.g. see Japanese Patent No. 3107287).

In a case of a photovoltaic cell having a point contact structure at the opposite side of a light-receiving surface (hereinafter also referred to as “back surface”), the recombination speed of minority carriers at a surface of a part of the back surface other than an aluminum electrode has to be suppressed. For this purpose, a SiO₂ film, etc. have been proposed as a semiconductor substrate passivation film (hereinafter also referred to simply as “passivation film”) for the back surface (e.g. see Japanese Patent Application Laid-Open (JP-A) No. 2004-6565). As a passivation effect by forming such an oxide film, there is an effect of terminating a dangling bond of silicon atoms at the surface of the back surface of a silicon substrate so as to reduce the surface level density which causes a recombination.

As another method for suppressing a recombination of minority carriers, there is a method in which the minority carrier density is reduced by an electric field generated by a fixed charge in a passivation film. Such a passivation effect is called generally as an electric field effect, and an aluminum oxide (Al₂O₃) film or the like has been proposed as a material having a negative fixed charge (e.g. see Japanese Patent No. 4767110).

Such a passivation film is generally formed by a method such as an Atomic Layer Deposition (ALD) method or a Chemical Vapor Deposition (CVD) method (e.g. see Journal of Applied Physics, 104 (2008), 113703). Further, as a simple technique for forming an aluminum oxide film on a semiconductor substrate, a technique by a sol-gel method has been proposed (e.g. see Thin Solid Films, 517 (2009), 6327-6330; and Chinese Physics Letters, 26 (2009), 088102).

### SUMMARY OF INVENTION

### Technical Problem

Since the technique described in Journal of Applied Physics, 104 (2008), 113703 includes a complicated process step such as vapor deposition, improvement in productivity may be difficult sometimes. As for the technique described in Thin Solid Films, 517 (2009), 6327-6330 and Chinese Physics Letters, 26 (2009), 088102, a composition for forming a passivation film used therein is liable to troubles such as gelation with time, and the storage stability has been hardly satisfactory.

The present invention was carried out in view of the above problems in prior art, with an object to provide a simple technique for forming a passivation film in a desired shape and a composition for forming a passivation film superior in storage stability. Another object of the invention is to provide a semiconductor substrate and a photovoltaic cell element provided with a passivation film using the composition for forming a passivation film. Still another object of the invention is to provide a production method for the semiconductor substrate and the photovoltaic cell element provided with a passivation film using the composition for forming a passivation film.

### Solution to Problem

Specific means for achieving the objects are as follows.

<1> A composition for forming a passivation film, comprising: an organic aluminum compound represented by the following General Formula (I); and a resin:

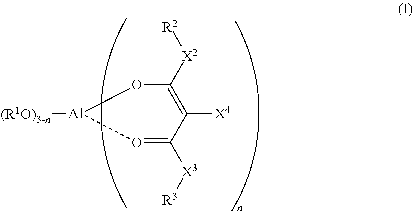

wherein in the formula, R¹'s each independently represent an alkyl group having 1 to 8 carbon atoms; n represents an integer of from 0 to 3; X² and X³ each independently represent an oxygen atom or a methylene group; R², R³ and R⁴ each independently represent a hydrogen atom or an alkyl group having 1 to 8 carbon atoms.

<2> The composition for forming a passivation film according to <1> above, wherein R¹'s in General Formula (I) each independently represent an alkyl group having 1 to 4 carbon atoms.

<3> The composition for forming a passivation film according to <1> or <2> above, wherein in General Formula (I), n is an integer of from 1 to 3, and R⁴'s each independently represent a hydrogen atom or an alkyl group having 1 to 4 carbon atoms.

<4> The composition for forming a passivation film according to any one of <1> to <3> above, wherein the content of the resin is from 0.1 mass % to 30 mass %.

<5> A semiconductor substrate provided with a passivation film, comprising:

a semiconductor substrate; and

a passivation film which is a heat-treated product layer of the composition for forming a passivation film according to any one of <1> to <4> above and which is provided on all or a part of a surface of the semiconductor substrate.

<6> A method of producing a semiconductor substrate provided with a passivation film, the method comprising:

forming a composition layer using the composition for forming a passivation film according to any one of <1> to <4> above on all or a part of a surface of a semiconductor substrate; and

heat-treating the composition layer to form a passivation film.

<7> A photovoltaic cell element, comprising:

a semiconductor substrate having a p-n junction of a p-type layer and an n-type layer;

a passivation film which is a heat-treated product layer of the composition for forming a passivation film according to any one of <1> to <4> above and is provided on all or a part of a surface of the semiconductor substrate; and

an electrode arranged on at least one of the p-type layer and the n-type layer of the semiconductor substrate.

<8> A method of producing a photovoltaic cell element, the method comprising:

forming a composition layer by using the composition for forming a passivation film according to any one of <1> to <4> above on a semiconductor substrate, the semiconductor substrate comprising a p-n junction of a p-type layer and an n-type layer and an electrode arranged on at least one of the p-type layer and the n-type layer, the composition layer being formed on one or both surfaces having the electrode of the semiconductor substrate; and

heat-treating the composition layer to form a passivation film.

### Advantageous Effects of Invention

According to the invention, a composition for forming a passivation film which enables the formation of a passivation film in a desired shape by a simple technique, and which has an excellent storage stability can be provided. According to the invention, a semiconductor substrate and a photovoltaic cell element provided with a passivation film can be provided using the composition for forming a passivation film. Further, according to the invention, production methods for a semiconductor substrate and a photovoltaic cell element provided with a passivation film using the composition for forming a passivation film can be provided.

### BRIEF DESCRIPTION OF DRAWINGS

FIG. 1 is a schematic cross-sectional view of an example of a production method of a photovoltaic cell element provided with a passivation film according to an embodiment of the present invention.

FIG. 2 is a schematic cross-sectional view of another example of a production method of a photovoltaic cell element provided with a passivation film according to an embodiment of the present invention.

FIG. 3 is a schematic cross-sectional view of a back contact photovoltaic cell element provided with a passivation film according to an embodiment of the present invention.

FIG. 4 is a plan view of an example of a screen mask plate for forming an electrode according to an embodiment of the present invention.

### DESCRIPTION OF EMBODIMENTS

The term “step” as used herein includes not only an independent step, but also a step which may not be clearly separated from another step, insofar as an intended function of the step can be attained. A numerical range expressed by “x to y” includes herein the values of x and y in the range as the minimum and maximum values, respectively. In referring herein to a content of a component in a composition, when plural substances exist corresponding to a component in the composition, the content means, unless otherwise specified, the total amount of the plural substances existing in the composition.

<Composition for Forming Passivation Film>

A composition for forming a passivation film according to the invention contains at least one organic aluminum compound represented by the following General Formula (I) and at least one resin. The composition for forming a passivation film may further contain, if necessary, another component.

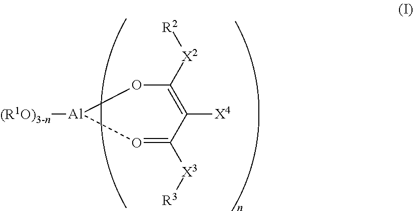

In the formula, R¹'s each independently represent an alkyl group having 1 to 8 carbon atoms; n represents an integer of from 0 to 3; X² and X³ each independently represent an oxygen atom or a methylene group; R², R³ and R⁴ each independently represent a hydrogen atom or an alkyl group having 1 to 8 carbon atoms. In this regard, when any of R¹ to R⁴, X², and X³ exists in plurality, the groups existing in plurality and represented by the same symbol may be the same as or different from one another.

A passivation film having an excellent passivation effect can be formed into a desired shape by applying the composition for forming a passivation film containing a specific organic aluminum compound and a resin to a semiconductor substrate to form a composition layer in the desired shape, and heat-treating the same. A technique according to the invention is a simple method with high productivity, which does not require a vapor deposition apparatus, etc. Further, the same can form a passivation film in a desired shape without requiring a complicated step such as mask process. Meanwhile, the composition for forming a passivation film can suppress occurrence of a trouble such as gelation owing to the specific organic aluminum compound contained to impart superior storage stability with time.

The passivation effect of a semiconductor substrate can be evaluated herein by performing a measurement of the effective lifetime of a minority carrier in a semiconductor substrate imparted with a passivation film by a microwave reflectance photoconductivity decay method using an instrument such as WT-2000PVN manufactured by Semilab Japan K.K.

In this regard, effective lifetime τ is represented by the bulk lifetime τ_{b} inside a semiconductor substrate and the surface lifetime τₛ in a surface of a semiconductor substrate according to the following Formula (A). Since τₛ becomes large when the surface level density of a semiconductor substrate is small, the effective lifetime τ becomes large. Further, when there are fewer defects, such as a dangling bond inside a semiconductor substrate, the bulk lifetime τ_{b} becomes longer and the effective lifetime τ becomes longer. In other words, by measuring effective lifetime τ, interface characteristics between a passivation film and a semiconductor substrate and internal characteristics of a semiconductor substrate such as a dangling bond can be evaluated.

1/τ=1/τ_{b}+1/τₛ (A)

In this regard, a longer effective lifetime means a retarded recombination speed of minority carriers. Further, the conversion efficiency can be improved by constructing a photovoltaic cell element with a semiconductor substrate having longer effective lifetime.

Further, the stability of a composition for forming a passivation film can be evaluated by viscosity change with time. Specifically, the stability may be evaluated by comparing a shear viscosity (η⁰) at a shear rate of 1.0 s⁻¹ of a composition for forming a passivation film immediately after (within 12 hours or less) the preparation thereof and a shear viscosity (η³⁰) at a shear rate of 1.0 s⁻¹ of the composition for forming a passivation film after storage at 25° C. for 30 days, and for example rated by a viscosity change rate (%) with time. The viscosity change rate (%) with time is obtained by dividing an absolute value of a difference between the shear viscosity immediately after preparation and the shear viscosity after 30 days by the shear viscosity immediately after preparation, and specifically calculated according to the formula shown below. The viscosity change rate of a composition for forming a passivation film is preferably 30% or less, more preferably 20% or less, and further preferably 10% or less.

Viscosity change rate (%)=|η³⁰−η⁰|/η⁰×100 (Formula)

(Organic Aluminum Compound)

The composition for forming a passivation film contains at least one organic aluminum compound represented by General Formula (I). The organic aluminum compound is a compound such as an aluminum alkoxide or an aluminum chelate, and preferably has an aluminum chelate structure in addition to an aluminum alkoxide structure. The organic aluminum compound is changed to aluminum oxide (Al₂O₃) by a heat treatment as described also in Journal of the Ceramic Society of Japan, 97 (1989) 369-399.

The inventors of the present invention consider as follows concerning the reason why a passivation film with superior passivation effect can be formed when a composition for forming a passivation film contains an organic aluminum compound represented by General Formula (I).

It can be so understood that an aluminum oxide formed by heat-treating a composition for forming a passivation film containing an organic aluminum compound with a specific structure tends to form an amorphous state and generate a defect in aluminum atoms or the like, so as to have a strong negative fixed charge near the interface with a semiconductor substrate. It is further understood that the strong negative fixed charge generates an electric field near the interface with a semiconductor substrate to decrease the concentration of minority carriers, and as the result carrier recombination speed at the interface can be suppressed, whereby a passivation film with superior passivation effect is formed.

Further, as a cause of a strong negative fixed charge, it is also conceivable that a 4-coordinated aluminum oxide layer is formed near the interface with a semiconductor substrate. In this regard, the state of a 4-coordinated aluminum oxide layer, which is a causative specie of a negative fixed charge on a semiconductor substrate surface, can be examined in terms of bonding mode by analyzing a cross-section of a semiconductor substrate by an electron energy loss spectroscopy method (EELS) with a scanning transmission electron microscope (STEM). A 4-coordinated aluminum oxide is considered to have a structure, in which the central silicon of silicon dioxide (SiO₂) is replaced isomorphously with aluminum, and it has been known that the same is formed at an interface between silicon dioxide and aluminum oxide as a negative electric charge source as in the case of zeolite or clay.

The state of formed aluminum oxide may be checked by an analysis of an X-ray diffraction (XRD) spectrum. For example, when an XRD does not show a specific diffraction pattern, it indicates an amorphous structure. Further, a negative fixed charge of aluminum oxide may be analyzed by a capacitance voltage measurement (CV) method. In this connection, a surface level density obtained by a CV method with respect to a heat-treated product layer containing aluminum oxide formed from a composition for forming a passivation film according to the invention may occasionally become higher compared to an aluminum oxide layer formed by an ALD or CVD method. However, a passivation film formed from a composition for forming a passivation film according to the invention has a large field effect so as to decrease the concentration of minority carriers and extend the surface lifetime τₛ. Consequently, the surface level density is relatively not important.

In General Formula (I), R¹'s each independently represent an alkyl group having 1 to 8 carbon atoms. An alkyl group represented by R¹ may be in a form of straight-chain or branched chain. Specific examples of an alkyl group represented by R¹ include a methyl group, an ethyl group, a propyl group, an isopropyl group, a butyl group, an isobutyl group, a sec-butyl group, a t-butyl group, a hexyl group, an octyl group, and an ethylhexyl group. Among them, an alkyl group represented by R¹ is preferably an unsubstituted alkyl group having 1 to 8 carbon atoms from viewpoints of storage stability and passivation effect, and more preferably an unsubstituted alkyl group having 1 to 4 carbon atoms.

In General Formula (I), n represents an integer of from 0 to 3. n is preferably an integer of from 1 to 3 from a viewpoint of storage stability, and more preferably 1 or 3. Meanwhile, X² and X³ each independently represent an oxygen atom or a methylene group. Preferably, at least one of X² and X³ is an oxygen atom from a viewpoint of storage stability.

In General Formula (I), R², R³ and R⁴ each independently represent a hydrogen atom or an alkyl group having 1 to 8 carbon atoms. An alkyl group represented by R², R³ or R⁴ may be in a form of straight-chain or branched chain. Specific examples of an alkyl group represented by R², R³ or R⁴ include a methyl group, an ethyl group, a propyl group, an isopropyl group, a butyl group, an isobutyl group, a sec-butyl group, a t-butyl group, a hexyl group, an octyl group, and an ethylhexyl group.

Among them, it is preferable that an alkyl group represented by R² or R³ independently represents a hydrogen atom or an unsubstituted alkyl group having 1 to 8 carbon atoms from viewpoints of storage stability and passivation effect, and more preferably a hydrogen atom or an unsubstituted alkyl group having 1 to 4 carbon atoms.

Further, R⁴ is preferably a hydrogen atom or an unsubstituted alkyl group having 1 to 8 carbon atoms from viewpoints of storage stability and passivation effect, and more preferably a hydrogen atom or an unsubstituted alkyl group having 1 to 4 carbon atoms.

From viewpoints of storage stability and passivation effect, the organic aluminum compound represented by General Formula (I) is preferably at least one selected from the group consisting of a compound in which n is 0, and R¹'s each independently represent an alkyl group having 1 to 4 carbon atoms, and a compound in which n is from 1 to 3, R¹'s each independently represent an alkyl group having 1 to 4 carbon atoms, at least one of X² and X³ is an oxygen atom, R² and R³ each independently are a hydrogen atom or an alkyl group having 1 to 4 carbon atoms, and R⁴ is a hydrogen atom or an alkyl group having 1 to 4 carbon atoms; and more preferably at least one selected from the group consisting of a compound in which n is 0, and R¹ is an unsubstituted alkyl group having 1 to 4 carbon atoms, and a compound in which n is from 1 to 3, R¹ is an unsubstituted alkyl group having 1 to 4 carbon atoms, at least one of X² and X³ is an oxygen atom, R² or R³ bonded to the oxygen atom is an alkyl group having 1 to 4 carbon atoms, and when X² or X³ is a methylene group, R² or R³ bonded to the methylene group is a hydrogen atom, and R⁴ is a hydrogen atom.

Specific examples of an aluminum trialkoxide, which is an organic aluminum compound represented by General Formula (I) wherein n is 0, include trimethoxy aluminum, triethoxy aluminum (aluminum ethylate), triisopropoxy aluminum (aluminum isopropylate), tri-sec-butoxy aluminum (aluminum sec-butyrate), mono-sec-butoxy-diisopropoxy aluminum (mono-sec-butoxy aluminum diisopropylate), tri-tert-butoxy aluminum, and tri-n-butoxy aluminum.

An organic aluminum compound represented by General Formula (I) in which n is from 1 to 3, may be prepared by mixing the aluminum trialkoxide and a compound having a specific structure having 2 carbonyl groups. Also, a commercially-supplied aluminum chelate compound may be used.

When the aluminum trialkoxide and a compound having a specific structure having 2 carbonyl groups are mixed, at least a part of the alkoxide groups in the aluminum trialkoxide is replaced with the compound having a specific structure to form an aluminum chelate structure. In that event, if necessary, a solvent may be present, and a heat treatment or catalyst addition may be performed. When at least a part of the aluminum alkoxide structure is replaced to an aluminum chelate structure, the stability of an organic aluminum compound with respect to hydrolysis or polymerization reaction is improved, and the storage stability of a composition for forming a passivation film containing the same can be improved.

As a compound having a specific structure having 2 carbonyl groups, at least one selected from the group consisting of a β-diketone compound, a β-ketoester compound, and a malonic acid diester is preferable from a viewpoint of storage stability. Specific examples of the compound having a specific structure having 2 carbonyl groups include a β-diketone compound such as acetylacetone, 3-methyl-2,4-pentanedione, 2,3-pentanedione, 3-ethyl-2,4-pentanedione, 3-butyl-2,4-pentanedione, 2,2,6,6-tetramethyl-3,5-heptanedione, 2,6-dimethyl-3,5-heptanedione, or 6-methyl-2,4-heptanedione; a β-ketoester compound such as methyl acetoacetate, ethyl acetoacetate, propyl acetoacetate, isobutyl acetoacetate, butyl acetoacetate, tert-butyl acetoacetate, pentyl acetoacetate, isopentyl acetoacetate, hexyl acetoacetate, n-octyl acetoacetate, heptyl acetoacetate, 3-pentyl acetoacetate, ethyl 2-acetylheptanoate, ethyl 2-butylacetoacetate, ethyl 4,4-dimethyl-3-oxovalerate, ethyl 4-methyl-3-oxovalerate, ethyl 2-ethylacetoacetate, ethyl hexylacetoacetate, methyl 4-methyl-3-oxovalerate, isopropyl acetoacetate, ethyl 3-oxohexanoate, ethyl 3-oxovalerate, methyl 3-oxovalerate, methyl 3-oxohexanoate, ethyl 2-methylacetoacetate, ethyl 3-oxoheptanoate, methyl 3-oxoheptanoate, or methyl 4,4-dimethyl-3-oxovalerate; and a malonic acid diester, such as dimethyl malonate, diethyl malonate, dipropyl malonate, diisopropyl malonate, dibutyl malonate, di-tert-butyl malonate, dihexyl malonate, tert-butyl ethyl malonate, diethyl methylmalonate, diethyl ethylmalonate, diethyl isopropylmalonate, diethyl butylmalonate, diethyl sec-butylmalonate, diethyl isobutylmalonate, or diethyl 1-methylbutylmalonate.

When the organic aluminum compound has an aluminum chelate structure, there is no particular restriction on the number of aluminum chelate structures, insofar as it is from 1 to 3. Among others, 1 or 3 is preferable from a viewpoint of storage stability. The number of aluminum chelate structures may be regulated by, for example, changing appropriately the mixing ratio of the aluminum trialkoxide to a compound which is capable of forming a chelate with aluminum. Further, a compound having a desired structure may be selected from commercially-supplied aluminum chelate compounds.

Among organic aluminum compounds represented by General Formula (I), specifically, use of an organic aluminum compound in which n is from 1 to 3 is preferable from viewpoints of reactivity during a heat treatment and storage stability as a composition. The use of at least one selected from the group consisting of aluminum ethyl acetoacetate diisopropylate, aluminum tris(ethyl acetoacetate), aluminum monoacetyl acetonate bis(ethyl acetoacetate), and aluminum tris(acetyl acetonate) is more preferable, and the use of aluminum ethyl acetoacetate diisopropylate is further preferable.

The presence of an aluminum chelate structure in the organic aluminum compound may be confirmed by an analysis method used ordinarily. For example, it may be confirmed by using an infrared spectrum, a nuclear magnetic resonance spectrum, a melting point, or the like.

The content of the organic aluminum compound to be contained in the composition for forming a passivation film may be selected appropriately according to need. The content of the organic aluminum compound in the composition for forming a passivation film may be from 1 mass % to 70 mass %, preferably from 3 mass % to 60 mass %, more preferably from 5 mass % to 50 mass %, and further preferably from 10 mass % to 30 mass %, from viewpoints of storage stability and passivation effect.

The organic aluminum may be liquid or solid, without any particular restriction. From viewpoints of passivation effect and storage stability, the uniformity of a passivation film to be formed is improved and a desired passivation effect can be stably obtained, insofar as the aluminum compound is superior in stability at normal temperature, and solubility or dispersibility.

(Resin)

The composition for forming a passivation film contains at least one resin. By containing a resin, a composition layer, which is formed by applying the composition for forming a passivation film on to a semiconductor substrate, can acquire improved shape stability, so that a passivation film can be formed selectively in a desired shape in a region in which the composition layer has been formed.

There is no particular restriction on the kind of resin. Among others, a resin of which viscosity may be adjusted into a range suitable for forming a favorable pattern when the composition for forming a passivation film is applied to a semiconductor substrate, is preferable. Specific examples of the resin include a poly(vinyl alcohol) resin; a poly(acrylamide) resin; a poly(vinyl amide) resin; a polyvinyl pyrrolidone resin; a poly(ethylene oxide) resin; a poly(sulfonic acid) resin; an acrylamide alkylsulfonic acid resin; cellulose; a cellulose resin such as cellulose ether, carboxymethyl cellulose, hydroxyethyl cellulose, or ethyl cellulose; gelatin and a gelatin derivative; starch and a starch derivative; a sodium alginate; xanthan and a xanthan derivative; guar and a guar derivative; scleroglucan and a scleroglucan derivative; tragacanth and a tragacanth derivative; dextrin and a dextrin derivative; a (meth)acrylic resin such as a (meth)acrylic acid resin or a (meth)acrylate resin such as an alkyl (meth)acrylate resin or a dimethyl aminoethyl (meth)acrylate resin; a butadiene resin; a styrenic resin; a siloxane resin; and a butyral resin; as well as a copolymer thereof.

Among them, a neutral resin not having an acidic or basic functional group is preferably used from viewpoints of storage stability and pattern formability, and more preferably a cellulose resin is used from a viewpoint that the viscosity and thixotropy can be easily adjusted even with a small amount.

There is no particular restriction on the molecular weight of the resin, and the molecular weight is preferably regulated appropriately according to a desired viscosity of a composition. The weight-average molecular weight of the resin is preferably from 100 to 10,000,000, and more preferably from 1,000 to 5,000,000, from viewpoints of storage stability and pattern formability. The weight-average molecular weight of the resin is determined by converting a molecular weight distribution measured by gel permeation chromatography using a calibration curve based on a standard polystyrene.

The resins are used singly or in a combination of two or more thereof.

The content of the resin in a composition for forming a passivation film may be selected appropriately according to need. The resin content is, for example, preferably from 0.1 mass % to 30 mass % in a composition for forming a passivation film. From a viewpoint of developing thixotropy allowing easy pattern formation, the resin content is more preferably from 1 mass % to 25 mass %, further preferably from 1.5 mass % to 20 mass %, and still further preferably from 1.5 mass % to 10 mass %.

The ratio of the contents of the organic aluminum compound and the resin in the composition for forming a passivation film may be selected appropriately according to need. Among others, the ratio of the content of the resin to the content of the organic aluminum compound (resin/organic aluminum compound) is preferably from 0.001 to 1000, more preferably from 0.01 to 100, and further preferably from 0.1 to 1, from viewpoints of pattern formability and storage stability.

(Solvent)

The composition for forming a passivation film preferably contains a solvent. When the composition for forming a passivation film contains a solvent, the viscosity thereof may be adjusted more easily so that the applicability may be improved and a more uniform heat-treated product layer may be formed. There is no particular restriction on the solvent, and it may be selected appropriately according to need. Among others, a solvent which is capable of dissolving the organic aluminum compound and the resin to yield a homogeneous solution, is preferable, and a solvent containing at least one organic solvent is more preferable.

Specific examples of a solvent include a ketone solvent such as acetone, methyl ethyl ketone, methyl n-propyl ketone, methyl isopropyl ketone, methyl n-butyl ketone, methyl isobutyl ketone, methyl n-pentyl ketone, methyl n-hexyl ketone, diethyl ketone, dipropyl ketone, diisobutyl ketone, trimethyl nonanone, cyclohexanone, cyclopentanone, methyl cyclohexanone, 2,4-pentanedione, or acetonyl acetone; an ether solvent such as diethyl ether, methyl ethyl ether, methyl n-propyl ether, diisopropyl ether, tetrahydrofuran, methyl tetrahydrofuran, dioxane, dimethyldioxane, ethylene glycol dimethyl ether, ethylene glycol diethyl ether, ethylene glycol di-n-propyl ether, ethylene glycol dibutyl ether, diethylene glycol dimethyl ether, diethylene glycol diethyl ether, diethylene glycol methyl ethyl ether, diethylene glycol methyl n-propyl ether, diethylene glycol methyl n-butyl ether, diethylene glycol di-n-propyl ether, diethylene glycol di-n-butyl ether, diethylene glycol methyl n-hexyl ether, triethylene glycol dimethyl ether, triethylene glycol diethyl ether, triethylene glycol methyl ethyl ether, triethylene glycol methyl n-butyl ether, triethylene glycol di-n-butyl ether, triethylene glycol methyl n-hexyl ether, tetraethylene glycol dimethyl ether, tetraethylene glycol diethyl ether, tetraethylene glycol methyl ethyl ether, tetraethylene glycol methyl n-butyl ether, tetraethylene glycol di-n-butyl ether, tetraethylene glycol methyl n-hexyl ether, tetraethylene glycol di-n-butyl ether, propylene glycol dimethyl ether, propylene glycol diethyl ether, propylene glycol di-n-propyl ether, propylene glycol dibutyl ether, dipropylene glycol dimethyl ether, dipropylene glycol diethyl ether, dipropylene glycol methyl ethyl ether, dipropylene glycol methyl n-butyl ether, dipropylene glycol di-n-propyl ether, dipropylene glycol di-n-butyl ether, dipropylene glycol methyl n-hexyl ether, tripropylene glycol dimethyl ether, tripropylene glycol diethyl ether, tripropylene glycol methyl ethyl ether, tripropylene glycol methyl n-butyl ether, tripropylene glycol di-n-butyl ether, tripropylene glycol methyl n-hexyl ether, tetrapropylene glycol dimethyl ether, tetrapropylene glycol diethyl ether, tetrapropylene glycol methyl ethyl ether, tetrapropylene glycol methyl n-butyl ether, tetrapropylene glycol di-n-butyl ether, tetrapropylene glycol methyl n-hexyl ether, or tetrapropylene glycol di-n-butyl ether; an ester solvent such as methyl acetate, ethyl acetate, n-propyl acetate, isopropyl acetate, n-butyl acetate, isobutyl acetate, sec-butyl acetate, n-pentyl acetate, sec-pentyl acetate, 3-methoxybutyl acetate, methylpentyl acetate, 2-ethylbutyl acetate, 2-ethylhexyl acetate, 2-(2-butoxyethoxy)ethyl acetate, benzyl acetate, cyclohexyl acetate, methylcyclohexyl acetate, nonyl acetate, methyl acetoacetate, ethyl acetoacetate, diethylene glycol methyl ether acetate, diethylene glycol monoethyl ether acetate, dipropylene glycol methyl ether acetate, dipropylene glycol ethyl ether acetate, glycol diacetate, methoxytriglycol acetate, ethyl propionate, n-butyl propionate, isoamyl propionate, diethyl oxalate, di-n-butyl oxalate, methyl lactate, ethyl lactate, n-butyl lactate, n-amyl lactate, ethylene glycol methyl ether propionate, ethylene glycol ethyl ether propionate, ethylene glycol methyl ether acetate, ethylene glycol ethyl ether acetate, propylene glycol methyl ether acetate, propylene glycol ethyl ether acetate, propylene glycol propyl ether acetate, γ-butyrolactone, or γ-valerolactone; an aprotic polar solvent such as acetonitrile, N-methyl pyrrolidinone, N-ethyl pyrrolidinone, N-propyl pyrrolidinone, N-butyl pyrrolidinone, N-hexyl pyrrolidinone, N-cyclohexyl pyrrolidinone, N,N-dimethyl formamide, N,N-dimethyl acetamide, or dimethyl sulfoxide; an alcohol solvent such as methanol, ethanol, n-propanol, isopropanol, n-butanol, isobutanol, sec-butanol, t-butanol, n-pentanol, isopentanol, 2-methylbutanol, sec-pentanol, t-pentanol, 3-methoxybutanol, n-hexanol, 2-methyl pentanol, sec-hexanol, 2-ethylbutanol, sec-heptanol, n-octanol, 2-ethylhexanol, sec-octanol, n-nonylalcohol, n-decanol, sec-undecyl alcohol, trimethylnonyl alcohol, sec-tetradecyl alcohol, sec-heptadecyl alcohol, phenol, cyclohexanol, methyl cyclohexanol, benzyl alcohol, ethylene glycol, 1,2-propylene glycol, 1,3-butylene glycol, diethylene glycol, dipropylene glycol, triethylene glycol, or tripropylene glycol; a glycol monoether solvent such as ethylene glycol monomethyl ether, ethylene glycol monoethyl ether, ethylene glycol monophenyl ether, diethylene glycol monomethyl ether, diethylene glycol monoethyl ether, diethylene glycol mono-n-butyl ether, diethylene glycol mono-n-hexyl ether, ethoxytriglycol, tetraethylene glycol mono-n-butyl ether, propylene glycol monomethyl ether, dipropylene glycol monomethyl ether, dipropylene glycol monoethyl ether, or tripropylene glycol monomethyl ether; terpene solvents such as a pinene such as α-pinene or β-pinene, a terpinene such as α-terpinene, a terpineol such as α-terpineol, myrcene, allo-ocimene, limonene, dipentene, terpineol, carvone, ocimene, or phellandrene; and water. The solvents may be used singly or in a combination of two or more thereof.

Among others, from viewpoints of applicability to a semiconductor substrate and pattern formability, the solvent preferably contains at least one selected from the group consisting of a terpene solvent, an ester solvent and an alcohol solvent, and more preferably at least one selected from the group consisting of a terpene solvent.

The content of a solvent in a composition for forming a passivation film is decided considering applicability, pattern formability, and storage stability. The content of a solvent in a composition for forming a passivation film is preferably, for example, from 5 mass % to 98 mass %, and more preferably from 10 mass % to 95 mass %, from viewpoints of applicability and pattern formability of the composition.

From a viewpoint of storage stability, it is preferable that in the composition for forming a passivation film, contents of an acidic compound and a basic compound are respectively 1 mass % or less, and more preferably 0.1 mass % or less, with respect to the composition for forming a passivation film.

Examples of the acidic compound include a Bronsted acid and a Lewis acid. Specific examples thereof include an inorganic acid such as hydrochloric acid or nitric acid, and an organic acid such as acetic acid. Examples of the basic compound include a Bronsted base and a Lewis base. Specific examples thereof include an inorganic base such as an alkali metal hydroxide or an alkaline earth metal hydroxide, and an organic base such as a trialkylamine or pyridine.

There is no particular restriction on the viscosity of the composition for forming a passivation film, and it may be selected appropriately depending on an application method onto a semiconductor substrate or the like. It may be, for example, from 0.01 Pa·s to 10,000 Pa·s. From a viewpoint of pattern formability, it is preferably from 0.1 Pa·s to 1,000 Pa·s. The viscosity is measured using a rotational shearing viscometer at 25° C. at a shear rate of 1.0 s⁻¹.

There is no particular restriction on the shear viscosity of the composition for forming a passivation film. From a viewpoint of pattern formability, a thixotropic ratio (η₁/η₂) calculated by dividing a shear viscosity η₁ at a shear rate of 1.0 s⁻¹ by a shear viscosity η₂ at a shear rate of 10 s⁻¹ is preferably from 1.05 to 100, and more preferably from 1.1 to 50. The shear viscosity is measured using a rotational shearing viscometer equipped with a cone-plate (diameter 50 mm, cone angle 1°) at a temperature of 25° C.

There is no particular restriction on a production method of the composition for forming a passivation film. The composition may be produced, for example, by mixing an organic aluminum compound and a resin, as well as, if necessary, a solvent by a mixing method ordinarily used. The resin may be dissolved in a solvent in advance and then mixed with the organic aluminum compound to produce a composition.

Further, the organic aluminum compound may be prepared by mixing an aluminum alkoxide and a compound which is capable of forming a chelate with aluminum. In this case, a solvent may appropriately be used or a heat treatment may be conducted. The thus prepared organic aluminum compound may be mixed with the resin or a solution containing the resin to produce a composition for forming a passivation film.

Components and the contents thereof in the composition for forming a passivation film may be examined by a thermal analysis such as TG/DTA, a spectroscopic analysis such as NMR or IR, a chromatographic analysis such as HPLC or GPC, or the like.

<Semiconductor Substrate with Passivation Film>

A semiconductor substrate provided with a passivation film according to the invention includes: a semiconductor substrate; and a passivation film which is a heat-treated product of the composition for forming a passivation film and which is formed on all or a part of a surface of the semiconductor substrate. The semiconductor substrate provided with a passivation film exhibits a superior passivation effect owing to the presence of a passivation film which is a layer composed of a heat-treated product of the composition for forming a passivation film mentioned above.

The semiconductor substrate may be either a p-type semiconductor substrate or an n-type semiconductor substrate. Especially, from a viewpoint of passivation effect, a surface of a semiconductor substrate, on which a passivation film is to be formed, is preferably a p-type layer. The p-type layer on a semiconductor substrate may be a p-type layer originated from a p-type semiconductor substrate, or formed on an n-type semiconductor substrate or a p-type semiconductor substrate as a p-type diffusion layer or a p⁺-type diffusion layer.

There is no particular restriction on the thickness of the semiconductor substrate, and the thickness may be selected appropriately according to an object. For example, the thickness may be from 50 μm to 1000 μm, and preferably from 75 μm to 750 μm.

There is no particular restriction on the thickness of a passivation film to be formed on the semiconductor substrate, and the thickness may be selected appropriately according to an object. For example, the thickness of a passivation film may be preferably from 5 nm to 50 μm, more preferably from 10 nm to 30 μm, and further preferably from 15 nm to 20 μm.

The film thickness of a passivation film is measured in a usual manner using a stylus step surface profiler (e.g. from Ambios Technology, Inc.).

There is no particular restriction on the shape of a passivation film, and it may be in a desired shape according to need. A passivation film may be formed on all of a surface of a semiconductor substrate, or only in a partial region.

The semiconductor substrate provided with a passivation film may be applied to a photovoltaic cell element, a light-emitting diode device, etc. When the semiconductor substrate is applied to, for example, a photovoltaic cell element, a photovoltaic cell element superior in conversion efficiency can be obtained.

<Production Method of Semiconductor Substrate with Passivation Film>

A method of producing a semiconductor substrate provided with a passivation film according to the invention includes: forming a composition layer by applying the composition for forming a passivation film on all or a part of a surface of a semiconductor substrate; and heat-treating the composition layer to form a passivation film. If necessary, the production method may include an additional step.

By using the composition for forming a passivation film, a passivation film having a superior passivation effect can be formed in a desired shape by a simple method.

There is no particular restriction on a semiconductor substrate, to which the composition for forming a passivation film is applied, and it may be selected appropriately from the substrates used ordinarily according to an object. There is no particular restriction on the semiconductor substrate, insofar as it is prepared by doping a p-type impurity or an n-type impurity to silicon, germanium, etc. Among others, a silicon substrate is preferable. Meanwhile, a semiconductor substrate may be either a p-type semiconductor substrate or an n-type semiconductor substrate. Especially, from a viewpoint of passivation effect, a surface of a semiconductor substrate, on which a passivation film is to be formed, is preferably a p-type layer. The p-type layer on a semiconductor substrate may be a p-type layer originated from a p-type semiconductor substrate, or formed on an n-type semiconductor substrate or a p-type semiconductor substrate as a p-type diffusion layer or a p⁺-type diffusion layer.

There is no particular restriction on the thickness of the semiconductor substrate, and the thickness may be selected appropriately according to an object. For example, the thickness may be from 50 μm to 1000 μm, and preferably from 75 μm to 750 μm.

The production method of a semiconductor substrate provided with a passivation film preferably has an additional step of applying an alkali aqueous solution to a semiconductor substrate before the step for forming a composition layer.

In other words, it is preferable to wash a surface of a semiconductor substrate with an alkali aqueous solution before applying the composition for forming a passivation film onto the semiconductor substrate.

By washing with an alkali aqueous solution, an organic substance, particles, etc. existing on a semiconductor substrate surface may be removed to enhance a passivation effect.

Examples of a washing method with an alkali aqueous solution include a generally known RCA clean. For example, a semiconductor substrate is dipped in a mixed solution of ammonia water and hydrogen peroxide water and treated at a temperature from 60° C. to 80° C. for removing and washing away the organic substance and particles.

The washing duration is preferably from 10 seconds to 10 min., and more preferably from 30 seconds to 5 min.

There is no particular restriction on a method of forming a composition layer by applying the composition for forming a passivation film onto a semiconductor substrate. Examples thereof include a method of applying the composition for forming a passivation film onto a semiconductor substrate using a publicly known coating method. Specific examples include a dipping method, a printing method such as screen printing, a spin coating method, brush coating, a spray method, a doctor blade method, a roll coater method, and an ink jet method. Among them, various printing methods, an ink jet method and the like are preferable from a viewpoint of pattern formability.

The application amount of the composition for forming a passivation film may be selected appropriately according to an object. For example, the amount may be appropriately adjusted so that the film thickness of a formed passivation film becomes a desired film thickness described below.

A passivation film may be formed on a semiconductor substrate by forming a heat-treated product layer derived from the composition layer by heat-treating a composition layer formed with the composition for forming a passivation film.

There is no particular restriction on heat treatment conditions of a composition layer, insofar as an organic aluminum compound contained in a composition layer is converted to aluminum oxide (Al₂O₃) as a heat-treated product. Especially, heat treatment conditions suitable for forming an amorphous Al₂O₃ layer not having a specific crystal structure, are preferable. When a passivation film is formed of an amorphous Al₂O₃ layer, a negative charge can be retained effectively owing to a passivation film so as to develop a better passivation effect. The heat treatment step may be divided into a drying step and an annealing step. Although after a drying step, a passivation effect does not appear yet, and a passivation effect appears after an annealing step. More specifically, the annealing temperature is preferably from 400° C. to 900° C., and more preferably from 450° C. to 800° C. Meanwhile, the annealing time may be selected appropriately according to the annealing temperature, etc. It may be, for example, from 0.1 hour to 10 hours, and preferably from 0.2 hour to 5 hours.

There is no particular restriction on the film thickness of a passivation film produced by the production method of a semiconductor substrate with a passivation film, and it may be selected appropriately according to an object. For example, the film thickness is preferably from 5 nm to 50 μm, more preferably from 10 nm to 30 μm, and further preferably from 15 nm to 20 μm.

The film thickness of a formed passivation film is measured in the usual manner using a stylus step surface profiler (e.g. from Ambios Technology, Inc.).

The production method for a semiconductor substrate provided with a passivation film may additionally include a step for drying a composition layer formed from the composition for forming a passivation film after application of the composition for forming a passivation film and before a step for forming a passivation film by annealing. By providing the step for drying a composition layer, a passivation film having a uniform passivation effect can be formed.

There is no particular restriction on a step for drying a composition layer, insofar as a solvent contained in the composition for forming a passivation film can be removed at least partly. The drying treatment may be, for example, a heat treatment at a temperature between 30° C. and 250° C. for from 1 min to 60 min, and preferably a heat treatment at a temperature between 40° C. to 220° C. for from 3 min to 40 min. The drying treatment may be carried out at normal pressure or under reduced pressure.

<Photovoltaic Cell Element>

A photovoltaic cell element according to the invention includes: a semiconductor substrate having a p-n junction of a p-type layer and an n-type layer; a passivation film which is a heat-treated product layer of the composition for forming a passivation film and is arranged on all or a part of a surface of the semiconductor substrate; and an electrode arranged on each of at least one layer selected from the group consisting of the p-type layer and the n-type layer of the semiconductor substrate. The photovoltaic cell element may additionally include, if necessary, another constituent.

Owing to the presence of a passivation film formed from the composition for forming a passivation film, the photovoltaic cell element is superior in conversion efficiency.

A surface of the semiconductor substrate, on which a passivation film is to be formed, may be either a p-type layer or an n-type layer, and is especially, from a viewpoint of conversion efficiency, preferably a p-type layer. The p-type layer on a semiconductor substrate may be a p-type layer originated from a p-type semiconductor substrate, or formed on an n-type semiconductor substrate or a p-type semiconductor substrate as a p-type diffusion layer or a p⁺-type diffusion layer.

There is no particular restriction on the thickness of the semiconductor substrate, and the thickness may be selected appropriately according to an object. For example, the thickness of the semiconductor substrate may be from 50 μm to 1000 μm, and preferably from 75 μm to 750 μm.

There is no particular restriction on the thickness of the passivation film to be formed on a semiconductor substrate, and the same may be selected appropriately according to an object. For example, it may be preferably from 5 nm to 50 μm, more preferably from 10 nm to 30 μm, and further preferably from 15 nm to 20 μm.

There is no particular restriction on the shape of a passivation film to be formed on a semiconductor substrate, and the shape thereof may be selected appropriately according to an object. The passivation film may be formed, for example, in a region outside an electrode arranged on a semiconductor substrate.

There is no restriction on the shape or dimension of the photovoltaic cell element. For example, a square, from 125 mm to 156 mm on a side, is preferable.

<Production Method of Photovoltaic Cell Element>

A method of producing a photovoltaic cell element according to the invention includes: forming an electrode on one or more layers selected from the group consisting of a p-type layer and an n-type layer on a semiconductor substrate having a p-n junction of the p-type layer and the n-type layer; forming a composition layer by applying the composition for forming a passivation film onto one or both surfaces, on which the electrode is formed, of the semiconductor substrate; and heat-treating the composition layer to form a passivation film. The production method of a photovoltaic cell element may, if necessary, include an additional step.

By use of the composition for forming a passivation film mentioned above, a photovoltaic cell element superior in conversion efficiency and provided with a passivation film of a semiconductor substrate superior in passivation effect can be produced by a simple method. Moreover, since a passivation film of a semiconductor substrate can be formed in a desired shape on a semiconductor substrate, on which an electrode has been formed, a photovoltaic cell element is superior in productivity.

A step for forming an electrode on one or more layers selected from the group consisting of a p-type layer and an n-type layer on a semiconductor substrate having a p-n junction may be carried out by selecting appropriately a method out of ordinary methods used for forming an electrode. For example, an electrode may be formed by applying an electrode formation paste, such as a silver paste or an aluminum paste, to a desired region on a semiconductor substrate, and, if necessary, conducting a sintering treatment. Details of a production method of an electrode are described above.

There is no particular restriction on the number and shape of electrodes to be formed, and these may be selected appropriately according to an object. Since a passivation film is formed using a composition for forming a passivation film in the invention, an electrode(s) in a desired number and a shape and a passivation film in a desired shape can be formed easily.

According to the invention, the step for forming an electrode may be performed before the step for forming a composition layer, or after the step for forming a composition layer or forming a passivation film. The step for forming an electrode is preferably carried out prior to the step for forming the composition layer, from a viewpoint of obtaining improved passivation effect.

A surface of a semiconductor substrate, on which the passivation film of a semiconductor substrate is to be provided, may be a p-type layer or an n-type layer. Among others, a p-type layer is preferable from a viewpoint of conversion efficiency.

Details of a method of forming a passivation film of a semiconductor substrate using a composition for forming a passivation film are similar to the production method of a semiconductor substrate provided with a passivation film as descried above, and preferable embodiments thereof are also the same.

There is no particular restriction on the thickness of a passivation film of a semiconductor substrate formed on the semiconductor substrate, and the thickness may be selected appropriately according to an object. For example, the thickness is preferably from 5 nm to 50 μm, more preferably from 10 nm to 30 μm, and further preferably from 15 nm to 20 μm.

Next, embodiments of the invention will be described hereinbelow referring to the drawings.

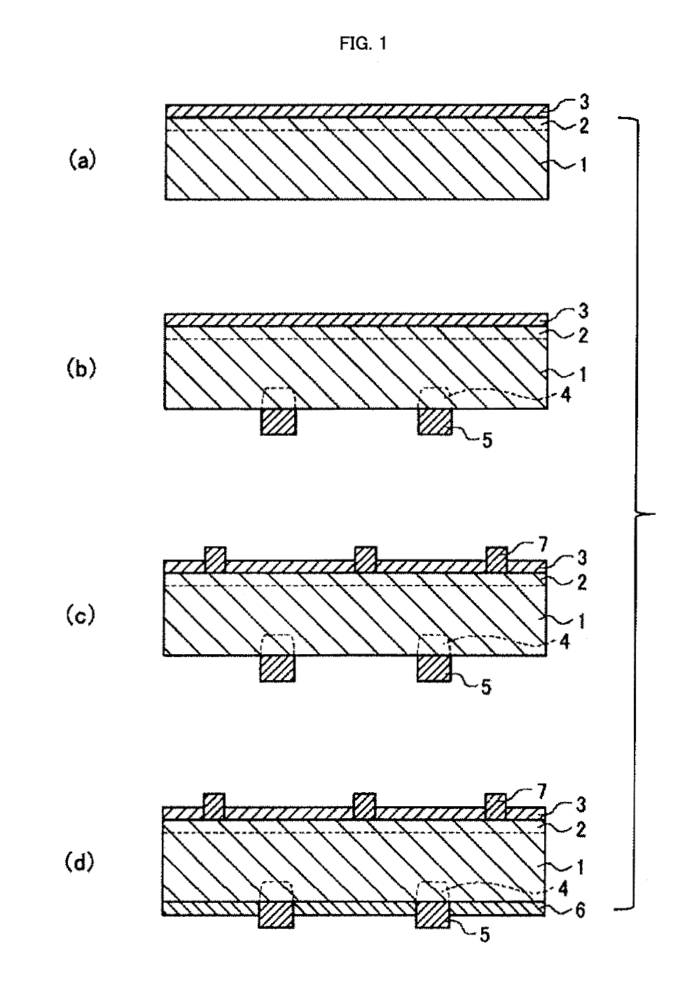

FIG. 1 is a schematic cross-sectional view of a flow diagram showing an example of a production method of a photovoltaic cell element provided with a passivation film of a semiconductor substrate according to an embodiment of the present invention. However, the flow diagram does not restrict by any means the invention.

As shown in FIG. 1(a), an n⁺-type diffusion layer 2 is formed in the vicinity of a top surface of a p-type semiconductor substrate 1, and an antireflection film 3 is formed on an outermost surface of the p-type semiconductor substrate 1. Examples of the antireflection film 3 include a silicon nitride film and a titanium oxide film. There may be another surface protective film (not illustrated) such as a silicon oxide film between the antireflection film 3 and the p-type semiconductor substrate 1. Further, a passivation film of a semiconductor substrate according to the invention may be used as a surface protective film.

Next, as shown in FIG. 1(b), a material, such as an aluminum electrode paste, for forming a back surface electrode 5 is coated onto a part of the back surface, followed by sintering, whereby back surface electrodes 5 are formed and aluminum atoms are diffused into the p-type semiconductor substrate 1 to form a p⁺-type diffusion layer 4.

Next, as shown in FIG. 1(c), an electrode-forming paste is coated on a light-receiving surface and then sintered to form a surface electrode 7. In a case in which an electrode-forming paste containing a glass powder having a fire-through property is used, a surface electrode 7 may be formed on the n⁺-type diffusion layer 2 through the antireflection film 3 as shown in FIG. 1(c), and an ohmic contact is attained.

Finally, as shown in FIG. 1(d), a composition for forming a passivation film is applied onto the p-type layer at the back surface, except for the region in which the back surface electrode 5 has been formed, to form a composition layer. The application may be performed, for example, by a coating method such as a screen printing. The composition layer formed on the p-type layer is then heat-treated to form a passivation film of a semiconductor substrate 6. A photovoltaic cell element superior in improved electric power generation efficiency can be produced by providing the passivation film 6 formed using the composition for forming a passivation film on the p-type layer at the back surface.

A photovoltaic cell element to be produced according to the production method containing process steps as shown in FIG. 1 can have a back surface electrode made of aluminum, etc. in a point contact structure, so that warping, etc. of a substrate can be mitigated. Further, by using the composition for forming a passivation film, a passivation film of a semiconductor substrate can be formed with high productivity only on a p-type layer except for a region in which an electrode has been arranged.

FIG. 1(d) shows a method of forming a passivation film only on a back surface. However, the composition for forming a passivation film may be applied also to a side surface of the semiconductor substrate 1 in addition to the back surface, and heat-treated to form a passivation film on the side surface (edge) of the semiconductor substrate 1 (not illustrated). By this means, a photovoltaic cell element with an improved electric power generation efficiency can be produced.

Further, the composition for forming a passivation film according to the invention may be coated only on a side surface and heat-treated to form a passivation film of a semiconductor substrate, without forming a passivation film of a semiconductor substrate on the back surface. The composition for forming a passivation film according to the invention is especially effective, if it is used in a place with many crystal defects such as a side surface.

In FIG. 1, an embodiment in which a passivation film is formed after an electrode is formed, is described. However, an electrode of aluminum, etc. may be formed in a desired region by vapor deposition, etc. after the formation of the passivation film.

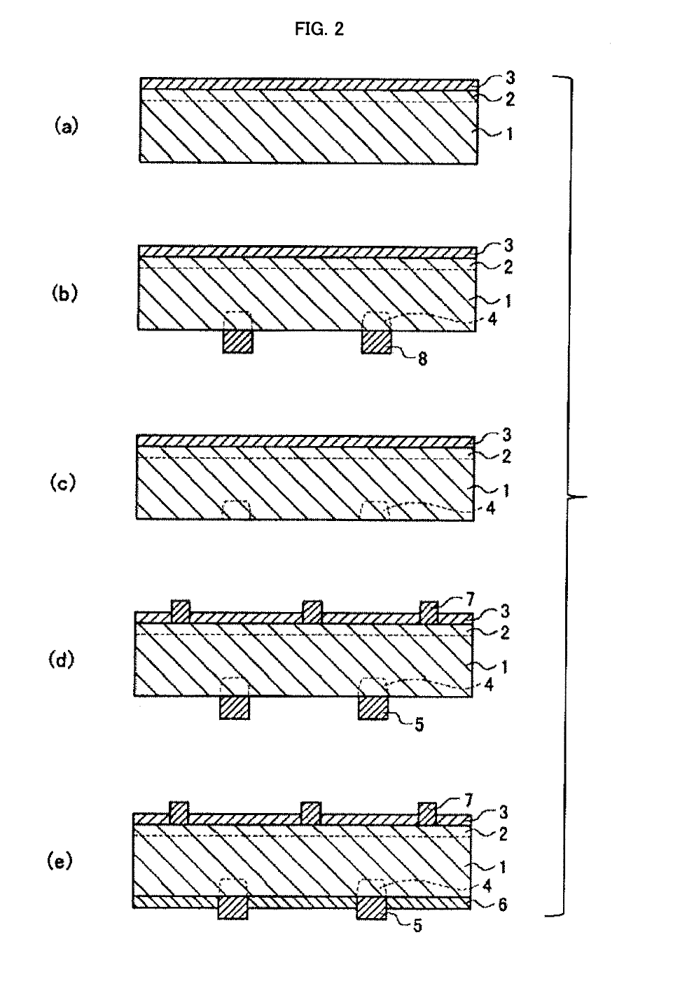

FIG. 2 is a schematic cross-sectional view of a flow diagram showing another example of a production method of a photovoltaic cell element provided with a passivation film according to an embodiment of the present invention. Specifically, FIG. 2 illustrates as cross-sectional views, a flow diagram including a step in which a p⁺-type diffusion layer is formed using an aluminum electrode paste or a composition for forming a p-type diffusion layer which is cable of forming a p⁺-type diffusion layer by a thermal diffusion treatment, and then a heat-treated product of the aluminum electrode paste or a heat-treated product of the composition for forming a p-type diffusion layer is removed. In this regard, examples of the composition for forming a p-type diffusion layer include a composition containing a substance containing an acceptor element and a glass component.

As shown in FIG. 2(a), an n⁺-type diffusion layer 2 is formed in the vicinity of a top surface of a p-type semiconductor substrate 1, and an antireflection film 3 is formed on a surface of the p-type semiconductor substrate 1. Examples of the antireflection film 3 include a silicon nitride film and a titanium oxide film.

Next, as shown in FIG. 2(b), a composition for forming a p-type diffusion layer is coated onto a part of the back surface, and then heat-treated to form a p⁺-type diffusion layer 4. On the p⁺-type diffusion layer 4, a heat-treated product 8 of the composition for forming a p-type diffusion layer is formed.

In this procedure, an aluminum electrode paste instead of the composition for forming a p-type diffusion layer may be used. When an aluminum electrode paste is used, an aluminum electrode 8 is formed on the p⁺-type diffusion layer 4.

Next, as shown in FIG. 2(c), the heat-treated product 8 of the composition for forming a p-type diffusion layer or the aluminum electrode 8 formed on the p⁺-type diffusion layer 4 is removed by a technique such as etching.

Next, as shown in FIG. 2(d), an electrode-forming paste is selectively coated on a part of a light-receiving surface (front surface) and a back surface, and heat-treated to form surface electrodes 7 on the light-receiving surface and back surface electrodes 5 on the back surface. In a case in which an electrode-forming paste containing a glass powder having a fire-through property is used as an electrode-forming paste to be applied to a light-receiving surface, a surface electrode 7 may be formed on the n⁺-type diffusion layer 2 through the antireflection film 3 as shown in FIG. 2(d), and an ohmic contact is attained.

Further, since a p⁺-type diffusion layer 4 has been formed in a region in which a back surface electrode is to be formed, the electrode-forming paste for forming a back surface electrode 5 is not limited to an aluminum electrode paste, and an electrode-forming paste which is capable of forming a lower resistance electrode, such as a silver electrode paste, may be used. From this, the electric power generation efficiency can be further enhanced.

Finally, as shown in FIG. 2(e), a composition for forming a passivation film is applied onto the p-type layer at the back surface except for the region in which the back surface electrode 5 has been formed, to form a composition layer. The application may be carried out, for example, by a coating method such as a screen printing. The composition layer formed on the p-type layer is then heat-treated to form a passivation film 6. A photovoltaic cell element superior in electric power generation efficiency can be produced by providing the passivation film 6 formed with the composition for forming a passivation film on the p-type layer of the back surface.

FIG. 2(e) shows a method of forming a passivation film only on a back surface. However, a material for forming a passivation film may be coated also to a side surface of the p-type semiconductor substrate 1 in addition to the back surface, and heat-treated to form a passivation film of a semiconductor substrate also on the side surface (edge) of the p-type semiconductor substrate 1 (not illustrated). By this means, a photovoltaic cell element with better electric power generation efficiency can be produced.

Further, the composition for forming a passivation film according to the invention may be applied only onto a side surface and heat-treated to form a passivation film, without forming a passivation film on a back surface. The composition for forming a passivation film according to the invention is especially effective, if it is used in a place with many crystal defects such as side surfaces.

In FIG. 2, an embodiment in which a passivation film is formed after an electrode has been formed is described. However, an electrode of aluminum, etc. may be formed in a desired region by vapor deposition, etc. after the formation of the passivation film.

Although, in the above embodiment, a case of a p-type semiconductor substrate with an n⁺-type diffusion layer formed on a light-receiving surface is described, a photovoltaic cell element may be produced even when an n-type semiconductor substrate with a p⁺-type diffusion layer formed on the light-receiving surface is used. In this case, an n⁺-type diffusion layer is formed on the back surface.

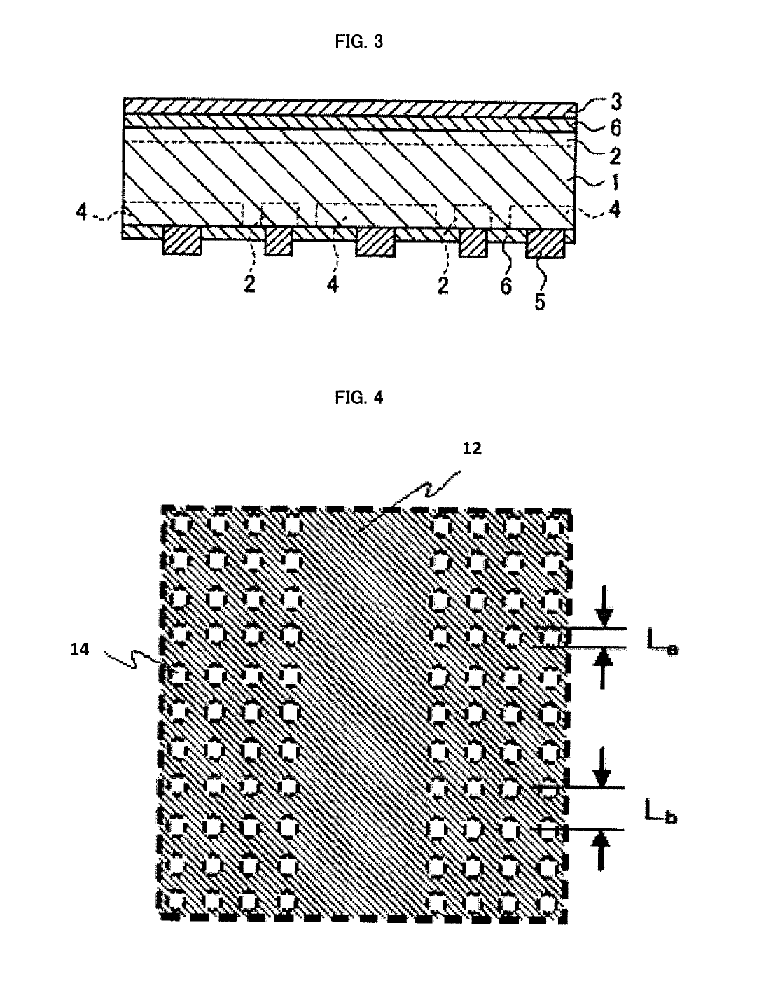

Further, the composition for forming a passivation film can be also used for forming a passivation film 6 on a light-receiving surface or a back surface of a back contact photovoltaic cell element, in which electrodes are provided only on the back surface as shown in FIG. 3.

As shown in a schematic cross-sectional view in FIG. 3, an n⁺-type diffusion layer 2 is formed in the vicinity of a top surface of a light-receiving surface of a p-type semiconductor substrate 1, and a passivation film 6 and an antireflection film 3 are formed on the surface of the p-type semiconductor substrate 1. As an antireflection film 3, a silicon nitride film, a titanium oxide film, or the like is known. Meanwhile, the passivation film 6 is formed by applying the composition for forming a passivation film according to the invention, followed by a heat treatment.

On a back surface of the p-type semiconductor substrate 1, back surface electrodes 5 are formed on a p⁺-type diffusion layer 4 and an n⁺-type diffusion layer 2 respectively, and a passivation film of a semiconductor substrate 6 is formed in a region of the back surface in which the electrodes are not formed.

A p⁺-type diffusion layer 4 may be formed by coating the composition for forming a p-type diffusion layer or an aluminum electrode paste in a desired region as mentioned above, followed by a heat treatment. Meanwhile, an n⁺-type diffusion layer 2 may be formed, for example, by coating a composition for forming an n-type diffusion layer, which is capable of forming an n⁺-type diffusion layer by a thermal diffusion treatment, onto a desired region, followed by a heat-treatment.

Examples of the composition for forming an n-type diffusion layer include a composition containing a substance containing a donor element and a glass component.

The back surface electrodes 5 to be arranged on the p⁺-type diffusion layer 4 and the n⁺-type diffusion layer 2 respectively may be formed with an ordinarily used electrode forming paste such as a silver electrode paste.

Meanwhile, a back surface electrode 5 to be provided on a p⁺-type diffusion layer 4 may be an aluminum electrode which is formed together with the p⁺-type diffusion layer 4 using an aluminum electrode paste.

The passivation film of a semiconductor substrate 6 formed on the back surface may be formed by applying the composition for forming a passivation film to a region in which a back surface electrode 5 has not been formed, followed by a heat-treatment.

Further, the passivation film of a semiconductor substrate 6 may be formed not only on the back surface of the semiconductor substrate 1, but also on a side surface (not illustrated).

A back contact photovoltaic cell element as shown in FIG. 3 does not have an electrode on the light-receiving surface, and therefore is superior in electric power generation efficiency. Further, since a passivation film is formed in a region of the back surface, in which an electrode has not been formed, the conversion efficiency can be further improved.

Although an example in which a p-type semiconductor substrate is used as a semiconductor substrate, is described above, a photovoltaic cell element superior in conversion efficiency can be produced in the same manner as above, even when an n-type semiconductor substrate is used.

<Photovoltaic Cell>

A photovoltaic cell is configured by including at least one photovoltaic cell element and a wiring material arranged on an electrode of the photovoltaic cell element. A photovoltaic cell may be, if necessary, also so configured that a plurality of photovoltaic cell elements are linked through a wiring material and sealed in a sealing material.

There is no particular restriction on the wiring material and sealing material, and they may be selected appropriately from those used ordinarily in the technical field.

There is no restriction on the size of the photovoltaic cell. It is preferably from 0.5 m² to 3 m².

### EXAMPLES

The invention will be described more specifically hereinbelow by way of examples, provided that the invention be not limited to the examples. Meanwhile, “%” is mass base, unless otherwise specified.

### Example 1

### Preparation of Composition for Forming Passivation Film

An organic aluminum compound solution was prepared by mixing 2.00 g of tri-sec-butoxy aluminum and 2.01 g of terpineol. Separately, 5.00 g of ethyl cellulose and 95.02 g of terpineol were mixed and stirred at 150° C. for 1 hour to prepare an ethyl cellulose solution. Then, 2.16 g of the organic aluminum compound solution and 3.00 g of the ethyl cellulose solution as obtained above were mixed to prepare a colorless, transparent solution as a composition 1 for forming a passivation film. The content of ethyl cellulose in the composition 1 for forming a passivation film was 2.9%, and the content of the organic aluminum compound was 21%.

The following evaluation was conducted with respect to the obtained composition 1 for forming a passivation film. The evaluation results are shown in Table 1.

(Formation of Passivation Film)

A mirror-surfaced single crystal p-type silicon substrate (50 mm square, thickness: 625 μm, produced by Sumco Corporation) was used as a semiconductor substrate. The silicon substrate was washed and pre-treated by immersion in an RCA cleaning liquid (FRONTIER CLEANER-A01, produced by Kanto Chemical Co., Ltd.) at 70° C. for 5 min.

Thereafter, the obtained composition 1 for forming a passivation film was applied to the pre-treated silicon substrate on all over a surface thereof by screen printing in such a manner that the film thickness after drying became 5 μm, followed by drying at 150° C. for 3 min. Next, the substrate was annealed at 550° C. for 1 hour, and left standing to cool at room temperature, thereby producing an evaluation substrate. The film thickness of the formed passivation film was 0.35 μm.

(Measurement of Effective Lifetime)

The effective lifetime (μs) of the evaluation substrate obtained above was measured by a microwave reflectance photoconductivity decay method at room temperature using a lifetime measuring apparatus (WT-2000PVN, manufactured by Semilab Japan K.K.). The obtained effective lifetime in a region of the evaluation substrate in which the composition for forming a passivation film has been applied was 111 μs.

The following evaluation was conducted with respect to the obtained composition 1 for forming a passivation film. The evaluation results are shown in Table 1.

(Thixotropic Ratio)

The shear viscosity of the composition 1 for forming a passivation film prepared above was measured immediately after the preparation (within 12 hours) using a rotational shearing viscometer (MCR301, manufactured by Anton Paar GmbH) and a cone-plate (diameter 50 mm, cone angle 1°) at a temperature of 25° C. and shear rates of 1.0 s⁻¹ and 10 s⁻¹, respectively.

The shear viscosity under a shear rate of 1.0 s⁻¹ (η₁) was 16.0 Pa·s, and the shear viscosity under a shear rate of 10 s⁻¹ (η₂) was 5.7 Pa·s. The thixotropic ratio (η₁/η₂) in a case in which the shear rates were 1.0 s⁻¹ and 10 s⁻¹ was 2.8.

(Storage Stability)

The shear viscosity of the composition 1 for forming a passivation film prepared above was measured immediately after the preparation (within 12 hours) and after storage at 25° C. for 30 days, respectively. Measurements of shear viscosity were carried out using MCR301 from Anton Paar GmbH and a cone-plate (diameter 50 mm, cone angle 1°) at a temperature of 25° C. and a shear rate of 1.0 s⁻¹.

The shear viscosity immediately after the preparation (η⁰) at 25° C. was 16.0 Pa·s, and the shear viscosity after storage at 25° C. for 30 days (η³⁰) was 17.3 Pa·s. As a result, a viscosity change rate (%) calculated according to the following formula was 8%.

Viscosity change rate (%)=|η³⁰−η⁰|/η⁰×100 (Formula)

### Example 2

An organic aluminum compound solution was obtained by mixing 4.79 g of tri-sec-butoxy aluminum, 2.56 g of ethyl acetoacetate, and 4.76 g of terpineol, and stirring the mixture at 25° C. for 1 hour. Separately, 12.02 g of ethyl cellulose and 88.13 g of terpineol were mixed and stirred at 150° C. for 1 hour to prepare an ethyl cellulose solution. Next, 2.93 g of the organic aluminum compound solution and 2.82 g of the ethyl cellulose solution were mixed to prepare a colorless, transparent solution as a composition 2 for forming a semiconductor substrate passivation film. The content of ethyl cellulose in the composition 2 for forming a passivation film was 5.9%, and the content of the organic aluminum compound was 21%.

A passivation film was formed on a pre-treated silicon substrate in the same manner as Example 1 except that the composition 2 for forming a passivation film prepared above was used, and the evaluation was performed in the same manner. The effective lifetime was 144 μs.

Thixotropic ratio and storage stability were evaluated in the same manner as above using the composition 2 for forming a passivation film prepared above. The results are shown in Table 1.

(Thixotropic Ratio)

The shear viscosity of the composition 2 for forming a passivation film prepared above was measured immediately after the preparation (within 12 hours) using a rotational shearing viscometer (MCR301, manufactured by Anton Paar GmbH) and a cone-plate (diameter 50 mm, cone angle 1°) at a temperature of 25° C. and shear rates of 1.0 s⁻¹ and 10 s⁻¹, respectively.

The shear viscosity under a shear rate of 1.0 s⁻¹ (η₁) was 41.5 Pa·s, and the shear viscosity under a shear rate of 10 s⁻¹ (η₂) was 28.4 Pa·s. The thixotropic ratio (η₁/η₂) in a case in which the shear viscosities were 1.0 s⁻¹ and 10 s⁻¹ was 1.5.

(Storage Stability)

The shear viscosity of the composition 2 for forming a passivation film prepared above immediately after the preparation at a temperature of 25° C. and a shear rate of 1.0 s⁻¹ was 41.5 Pa·s, and after storage at 25° C. for 30 days was 43.2 Pa·s. Therefore, the viscosity change rate indicating storage stability was 4%.

An IR spectrum of the organic aluminum compound in the organic aluminum compound solution prepared above was obtained using EXCALIBUR FTS-3000 (manufactured by Bio-Rad Laboratories, Inc.).

As a result, an absorption near 1600 cm⁻¹ characteristic of an oxygen-carbon bond coordinated to 4-coordinated aluminum and an absorption near 1500 cm⁻¹ characteristic of a carbon-carbon bond of a 6-membered cyclic complex were observed, respectively, to confirm that an aluminum chelate was formed.

### Example 3

An organic aluminum compound solution was obtained by mixing 4.96 g of tri-sec-butoxy aluminum, 3.23 g of diethyl malonate, and 5.02 g of terpineol, and stirring the mixture at 25° C. for 1 hour. Then, 2.05 g of the obtained organic aluminum compound solution, and 2.00 g of an ethyl cellulose solution prepared in the same manner as in Example 2 were mixed to prepare a colorless, transparent solution as a composition 3 for forming a semiconductor substrate passivation film. The content of ethyl cellulose in the composition 3 for forming a passivation film was 5.9%, and the content of the organic aluminum compound was 20%.

A passivation film was formed on a pre-treated silicon substrate in the same manner as Example 1 except that the composition 3 for forming a passivation film prepared above was used, and the evaluation was performed in the same manner. The effective lifetime was 96 μs.

Thixotropic ratio and storage stability were evaluated in the same manner as above, using the composition 3 for forming a passivation film prepared as above. The results are shown in Table 1.

(Thixotropic Ratio)

The shear viscosity of the composition 3 for forming a passivation film prepared above was measured immediately after the preparation (within 12 hours) using a rotational shearing viscometer (MCR301, manufactured by Anton Paar GmbH) and a cone-plate (diameter 50 mm, cone angle 1°) at a temperature of 25° C.

The shear viscosity under a shear rate of 1.0 s⁻¹ (η₁) was 90.7 Pa·s, the shear viscosity under a shear rate of 10 s⁻¹ (η₂) was 37.4 Pa·s, and shear viscosity under a shear rate of 100 s⁻¹ was 10.4 Pa·s. The thixotropic ratio (η₁/η₂) in a case in which the shear rates were 1.0 s⁻¹ and 10 s⁻¹ was 2.43.

(Storage Stability)

The shear viscosity of the composition 3 for forming a passivation film prepared above immediately after the preparation at a temperature of 25° C. and a shear rate of 1.0 s⁻¹ was 90.7 Pa·s, and after storage at 25° C. for 30 days was 97.1 Pa·s. Therefore, the viscosity change rate indicating storage stability was 7%.

An IR spectrum of the organic aluminum compound in the organic aluminum compound solution prepared above was obtained using EXCALIBUR FTS-3000 (manufactured by Bio-Rad Laboratories, Inc.).

As a result, an absorption near 1600 cm⁻¹ characteristic of an oxygen-carbon bond coordinated to 4-coordinated aluminum and an absorption near 1500 cm⁻¹ characteristic of a carbon-carbon bond of a 6-membered cyclic complex were observed, respectively, to confirm that an aluminum chelate was formed.

### Example 4

A passivation film was formed on the pre-treated silicon substrate in the same manner as Example 3 except that the composition 3 for forming a passivation film in Example 3 was applied onto a silicon substrate by screen printing in a form of strips with a width of 100 μm at intervals of 2 mm, and the evaluation was performed in the same manner.

The effective lifetime in a region in which the composition 3 for forming a passivation film had been applied, was 90 μs. Meanwhile, the effective lifetime in a region in which the composition 3 for forming a semiconductor substrate passivation film had not been applied, was 25 μs.

### Example 5

An aluminum paste (PVG-AD-02, produced by PVG Solutions Inc.) was applied on to a silicon substrate which had been subjected to a pre-treatment in the same manner as in Example 1, by screen printing in a form of strips with a width of about 200 μm at intervals of 2 mm, followed by sintering at 400° C. for 10 sec, at 850° C. for 10 sec, and at 650° C. for 10 sec, to thereby form an aluminum electrode with an thickness of 20 μm.

Next, the composition 3 for forming a passivation film prepared above was applied only to a region in which an aluminum electrode had not been formed, by screen printing, and then dried at 150° C. for 3 min. Then, the substrate was annealed at 550° C. for 1 hour and left standing at room temperature to cool to form a passivation film, thereby producing an evaluation substrate.

The effective lifetime in a region in which the passivation film had been formed, was 90 μs. Further, no foreign substance originated from the composition 3 for forming a passivation film was observed on a surface of the aluminum electrode.

### Example 6

A 10% ethyl cellulose solution was prepared by mixing 100.02 g of ethyl cellulose and 400.13 g of terpineol, and stirring the mixture at 150° C. for 1 hour. Separately, 9.71 g of aluminum ethylacetoacetate diisopropylate (trade name: ALCH, produced by Kawaken Fine Chemicals Co., Ltd.) and 4.50 g of terpineol were mixed. To this mixture, 15.03 g of the 10% ethyl cellulose solution was mixed to prepare a colorless, transparent solution as a composition 6 for forming a passivation film. The content of ethyl cellulose in the composition 6 for forming a passivation film was 5.1%, and the content of the organic aluminum compound was 33.2%.

A passivation film was formed on a pre-treated silicon substrate in the same manner as Example 1 except that the composition 6 for forming a passivation film prepared above was used, and the evaluation was performed in the same manner. The effective lifetime was 121 μs.

(Thixotropic Ratio)

The shear viscosity of the composition 6 for forming a passivation film prepared above was measured in the same manner as above.

The shear viscosity at a shear rate of 1.0 s⁻¹ (η₁) was 81.0 Pa·s, and the shear viscosity at a shear rate of 10 s⁻¹ (η₂) was 47.7 Pa·s. The thixotropic ratio (η₁/η₂) in a case in which the shear rates were 1.0 s⁻¹ and 10 s⁻¹ was 1.7.

(Storage Stability)

The shear viscosity of the composition 6 for forming a passivation film prepared above immediately after the preparation at a temperature of 25° C. and a shear rate of 1.0 s⁻¹ was 81.0 Pa·s, and after storage at 25° C. for 30 days was 80.7 Pa·s. Therefore, the viscosity change rate indicating storage stability was 0.4%.

(Print Smearing)

Evaluation of print smearing was performed by forming a pattern using the thus-prepared composition 6 for forming a passivation film on a silicon substrate by screen printing, and comparing a pattern shape immediately after the printing with a pattern shape after a heat treatment. For the screen printing, a screen mask plate having an opening pattern reverse to a screen mask plate for forming an electrode shown in FIG. 4 having circular-dot-shaped openings 14 and non-openings 12, was used (namely, a plate with non-openings corresponding to the dot-shaped openings 14 in FIG. 4). In the screen mask plate shown in FIG. 4, the dot diameter La of the dot-shaped openings 14 is 368 μm, and the dot interval Lb is 0.5 mm. In this regard, print smearing means a phenomenon, in which a composition layer formed with the composition for forming a passivation film printed on a silicon substrate expands in a planar direction of the silicon substrate compared to a used plate.

Specifically, a passivation film was formed as follows. The composition 6 for forming a passivation film prepared above was applied by a printing method to the entire surface of the regions corresponding to the non-openings 12 in FIG. 4. Then the silicon substrate applied with the composition 6 for forming a passivation film was heated at 150° C. for 3 min to evaporate a solvent for drying, to thereby form a composition layer. Next, the silicon substrate provided with the composition layer was annealed at a temperature of 700° C. for 10 min, and then left standing at room temperature to cool, thereby forming a passivation film. The film thickness of the formed passivation film was 0.55 μm.

Evaluation of print smearing was performed by measuring the diameter of a dot-shaped opening in a passivation film formed on a substrate after the heat treatment, namely the diameter of an opening in a region corresponding to the opening 14 in FIG. 4, where a passivation film was not formed. For a measurement, 10 diameters of the openings were measured and the mean value thereof was calculated as the diameter of the opening after the heat treatment. Print smearing was rated as A, when the decrease rate of a diameter of the opening after the heat treatment with respect to the dot diameter (La) immediately after the printing (368 μm) was less than 10%; B, when the same was not less than 10% but less than 30%, and C, when the same is not less than 30%. In the case, in which the rating was A or B, the composition for forming a passivation film is acceptable.

The composition 6 for forming a passivation film obtained above was rated as A with respect to print smearing.

### Example 7

A composition 7 for forming a passivation film was prepared as a colorless, transparent solution by mixing 10.12 g of aluminum ethylacetoacetate diisopropylate and 25.52 g of terpineol, and then further mixing 34.70 g of the 10% ethyl cellulose solution prepared in Example 6. The content of ethyl cellulose in the composition 7 for forming a passivation film was 4.9%, and the content of the organic aluminum compound was 14.4%.

A passivation film was formed on a pre-treated silicon substrate in the same manner as Example 1 except that the composition 7 for forming a passivation film prepared above was used, and the evaluation was performed in the same manner. The effective lifetime was 95 μs.

Thixotropic ratio, storage stability, and print smearing were evaluated in the same manner as above with respect to the composition 7 for forming a passivation film prepared above. The results are shown in Table 1.

(Thixotropic Ratio)

The shear viscosity at a shear rate of 1.0 s⁻¹ (η₁) was 43.4 Pa·s, and the shear viscosity at a shear rate of 10 s⁻¹ (η₂) was 27.3 Pa·s. The thixotropic ratio (η₁/η₂) in a case in which the shear rates were 1.0 s⁻¹ and 10 s⁻¹ was 1.6.

(Storage Stability)

The shear viscosity of the composition 7 for forming a passivation film immediately after the preparation at a temperature of 25° C. and a shear rate of 1.0 s⁻¹ was 43.4 Pa·s, and after storage at 25° C. for 30 days was 44.5 Pa·s. Therefore, the viscosity change rate indicating storage stability was 3%.

(Print Smearing)

The composition 7 for forming a semiconductor substrate passivation film was rated as A with respect to print smearing.

### Example 8

A composition 8 for forming a semiconductor substrate passivation film was prepared as a colorless, transparent solution by mixing 5.53 g of aluminum ethylacetoacetate diisopropylate and 6.07 g of terpineol, and then further mixing 9.93 g of the 10% ethyl cellulose solution prepared in Example 6. The content of ethyl cellulose in the composition 8 for forming a semiconductor substrate passivation film was 4.6%, and the content of the organic aluminum compound was 25.7%.

A passivation film was formed on a pre-treated silicon substrate in the same manner as Example 1 except that the composition 8 for forming a semiconductor substrate passivation film prepared above was used, and the evaluation was performed in the same manner. The effective lifetime was 110 μs.

Thixotropic ratio, storage stability, and print smearing were evaluated in the same manner as above with respect to the composition 8 for forming a passivation film prepared above. The results are shown in Table 1.

(Thixotropic Ratio)

The shear viscosity at a shear rate of 1.0 s⁻¹ (η₁) was 38.5 Pa·s, and the shear viscosity at a shear rate of 10 s⁻¹ (η₂) was 28.1 Pa·s. The thixotropic ratio (η₁/η₂) in a case in which the shear rates were 1.0 s⁻¹ and 10 s⁻¹ was 1.6.

(Storage Stability)

The shear viscosity of the composition 8 for forming a passivation film immediately after the preparation at a temperature of 25° C. and a shear rate of 1.0 s⁻¹ was 38.5 Pa·s, and after storage at 25° C. for 30 days was 39.7 Pa·s. Therefore, the viscosity change rate indicating storage stability was 3%.

(Print Smearing)

The composition 8 for forming a passivation film was rated as A with respect to print smearing.

### Example 9

A 4% ethyl cellulose solution was prepared by mixing 20.18 g of ethyl cellulose and 480.22 g of terpineol, followed by stirring at 150° C. for 1 hour. Then, 5.09 g of aluminum ethylacetoacetate diisopropylate, 5.32 g of the 4% ethyl cellulose solution, and 11.34 g of an aluminum hydroxide particle (HP-360, particle size (D50%): 3.2 μm, purity 99.0%, produced by Showa Denko K.K.) were mixed to prepare a composition 9 for forming a semiconductor substrate passivation film as a white suspension. The content of ethyl cellulose in the composition 9 for forming a semiconductor substrate passivation film was 1.0%, and the content of the organic aluminum compound was 23.4%.

A passivation film was formed on a pre-treated silicon substrate in the same manner as Example 1 except that the composition 9 for forming a semiconductor substrate passivation film prepared above was used, and the evaluation was performed in the same manner. The effective lifetime was 84 μs.

Thixotropic ratio, storage stability, and print smearing were evaluated in the same manner as above with respect to the composition 9 for forming a passivation film prepared above. The results are shown in Table 1.

(Thixotropic Ratio)

The shear viscosity at a shear rate of 1.0 s⁻¹ (η₁) was 33.5 Pa·s, and the shear viscosity at a shear rate of 10 s⁻¹ (η₂) was 25.6 Pa·s. The thixotropic ratio (η₁/η₂) in a case in which the shear rates were 1.0 s⁻¹ and 10 s⁻¹ was 1.3.

(Storage Stability)

The shear viscosity of the composition 9 for forming a passivation film immediately after the preparation at a temperature of 25° C. and a shear rate of 1.0 s⁻¹ was 33.5 Pa·s, and after storage at 25° C. for 30 days was 36.3 Pa·s. Therefore, the viscosity change rate indicating storage stability was 8%.

(Print Smearing)

The composition 9 for forming a passivation film was rated as A with respect to print smearing.

### Example 10

A composition 10 for forming a semiconductor substrate passivation film was prepared as a white suspension by mixing 5.18 g of aluminum ethylacetoacetate diisopropylate, 5.03 g of a 4% ethyl cellulose solution, 2.90 g of a silicon oxide particle (Aerosil 200, average particle size 12 nm, with a surface modified with a hydroxyl group; produced by Nippon Aerosil Co., Ltd.), and 6.89 g of terpineol. The content of ethyl cellulose in the composition 10 for forming a semiconductor substrate passivation film was 1.0%, and the content of the organic aluminum compound was 25.9%.

A passivation film was formed on a pre-treated silicon substrate in the same manner as Example 1 except that the composition 10 for forming a semiconductor substrate passivation film prepared above was used, and the evaluation was performed in the same manner. The effective lifetime was 97 μs.

Thixotropic ratio, storage stability, and print smearing were evaluated in the same manner as above with respect to the composition 10 for forming a passivation film prepared above. The results are shown in Table 1.

(Thixotropic Ratio)

The shear viscosity at a shear rate of 1.0 s⁻¹ (η₁) was 48.3 Pa·s, and the shear viscosity at a shear rate of 10 s⁻¹ (η₂) was 32.9 Pa·s. The thixotropic ratio (η₁/η₂) in a case in which the shear rates were 1.0 s⁻¹ and 10 s⁻¹ was 1.5.

(Storage Stability)

The shear viscosity of the composition 10 for forming a passivation film immediately after the preparation at a temperature of 25° C. and a shear rate of 1.0 s⁻¹ was 48.3 Pa·s, and after storage at 25° C. for 30 days was 50.1 Pa·s. Therefore, the viscosity change rate indicating storage stability was 4%.

(Print Smearing)

The composition 10 for forming a passivation film was rated as A with respect to print smearing.

### Example 11

A composition 11 for forming a semiconductor substrate passivation film was prepared as a white suspension by mixing 4.42 g of aluminum tris(ethyl acetoacetate) (Trade name: ALCH-TR, produced by Kawaken Fine Chemicals Co., Ltd.), 10.12 g of the 10% ethyl cellulose solution prepared in Example 6, and 10.53 g of terpineol. The content of ethyl cellulose in the composition 11 for forming a semiconductor substrate passivation film was 4.0%, and the content of the organic aluminum compound was 17.6%.

A passivation film was formed on a pre-treated silicon substrate in the same manner as Example 1 except that the composition 11 for forming a semiconductor substrate passivation film prepared above was used, and the evaluation was performed in the same manner. The effective lifetime was 88 μs.

Thixotropic ratio, storage stability, and print smearing were evaluated in the same manner as above with respect to the composition 11 for forming a passivation film prepared above. The results are shown in Table 1.

(Thixotropic Ratio)

The shear viscosity at a shear rate of 1.0 s⁻¹ (η₁) was 32.2 Pa·s, and the shear viscosity at a shear rate of 10 s⁻¹ (η₂) was 22.1 Pa·s. The thixotropic ratio (η₁/η₂) in a case in which the shear rates were 1.0 s⁻¹ and 10 s⁻¹ was 1.5.

(Storage Stability)

The shear viscosity of the composition 11 for forming a passivation film immediately after the preparation at a temperature of 25° C. and a shear rate of 1.0 s⁻¹ was 32.2 Pa·s, and after storage at 25° C. for 30 days was 33.4 Pa·s. Therefore, the viscosity change rate indicating storage stability was 4%.

(Print Smearing)

The composition 11 for forming a passivation film was rated as A with respect to print smearing.

### Example 12

A composition 12 for forming a semiconductor substrate passivation film was prepared as a white suspension by mixing 6.56 g of aluminum monoacetyl acetonate bis(ethyl acetoacetate) (Trade name: ALUMI-CHELATE D, 76% isopropyl alcohol solution, produced by Kawaken Fine Chemicals Co., Ltd.), 9.89 g of the 10% ethyl cellulose solution prepared in Example 6, and 9.78 g of terpineol. The content of ethyl cellulose in the composition 12 for forming a semiconductor substrate passivation film was 3.8%, and the content of the organic aluminum compound was 25.0%.

A passivation film was formed on a pre-treated silicon substrate in the same manner as Example 1 except that the composition 12 for forming a semiconductor substrate passivation film prepared above was used, and the evaluation was performed in the same manner. The effective lifetime was 102 μs.

Thixotropic ratio, storage stability, and print smearing were evaluated in the same manner as above with respect to the composition 12 for forming a passivation film prepared above. The results are shown in Table 1.

(Thixotropic Ratio)

The shear viscosity at a shear rate of 1.0 s⁻¹ (η₁) was 37.3 Pa·s, and the shear viscosity at a shear rate of 10 s⁻¹ (η₂) was 26.3 Pa·s. The thixotropic ratio (η₁/η₂) in a case in which the shear rates were 1.0 s⁻¹ and 10 s⁻¹ was 1.4.

(Storage Stability)

The shear viscosity of the composition 12 for forming a passivation film immediately after the preparation at a temperature of 25° C. and a shear rate of 1.0 s⁻¹ was 37.3 Pa·s, and after storage at 25° C. for 30 days was 39.5 Pa·s. Therefore, the viscosity change rate was 6%.

### (Print Smearing)

The composition 12 for forming a passivation film was rated as A with respect to print smearing.

### Comparative Example 1

An evaluation substrate was prepared in the same manner as Example 1 except that the composition 1 for forming a semiconductor substrate passivation film in Example 1 was not coated, and the substrate was evaluated by measuring effective lifetime. The effective lifetime was 20 μs.

### Comparative Example 2

A colorless, transparent composition C2 was prepared by mixing 2.00 g of an Al₂O₃ particle (average particle size 1 μm, produced by Kojundo Chemical Lab. Co., Ltd.), 1.98 g of terpineol, and 3.98 g of an ethyl cellulose solution prepared in the same manner as in Example 2.

A passivation film was formed on a pre-treated silicon substrate in the same manner as Example 1 except that the composition C2 prepared above was used, and the evaluation was performed in the same manner. The effective lifetime was 21 μs.

### Comparative Example 3

A colorless, transparent composition C3 was prepared by mixing 2.01 g of tetraethoxysilane, 1.99 g of terpineol, and 4.04 g of an ethyl cellulose solution prepared in the same manner as in Example 2.

A passivation film was formed on a pre-treated silicon substrate in the same manner as Example 1 except that the composition C3 prepared above was used, and the evaluation was performed in the same manner. The effective lifetime was 23 μs.

### Comparative Example 4

A composition C4 was prepared by mixing 8.02 g of trisisopropoxyaluminum, 36.03 g of purified water, and 0.15 g of concentrated nitric acid (d=1.41), followed by stirring at 100° C. for 1 hour.

A passivation film was formed on a silicon substrate provided with an aluminum electrode in the same manner as Example 5 except that the composition C4 prepared above was used, and the evaluation was performed in the same manner.

The effective lifetime in a region in which the passivation film had been formed was 110 μs. Further, a foreign substance originated from the composition C4 for forming a semiconductor substrate passivation film was observed on a surface of the aluminum electrode.

(Storage Stability)

The shear viscosity of the composition C4 for forming a passivation film prepared above, immediately after the preparation at a temperature of 25° C. and a shear rate of 1.0 s⁻¹ was 67.5 Pa·s, and after storage at 25° C. for 30 days was 36,000 Pa·s. Therefore, the viscosity change rate was 532%.

TABLE 1

| | | | | Shear viscosity (Pa · S) | | | | |
|---|---|---|---|---|---|---|---|---|
| | Content (%) | | | 1.0 s⁻¹ | | 10 s⁻¹ | | |
| | Organic | | Effective | Immediately | | Immediately | | |
| | aluminum | Ethyl | lifetime | after | After | after | Thixotropic | Print |
| | compound | cellulose | (μs) | preparation | 30 days | preparation | ratio | smearing |
| Example 1 | 20.9 | 2.9 | 111 | 16.0 | 17.3 | 5.7 | 2.8 | — |
| Example 2 | 20.2 | 5.9 | 144 | 41.5 | 43.2 | 28.4 | 1.5 | — |
| Example 3 | 19.0 | 5.9 | 96 | 90.7 | 97.1 | 37.4 | 2.4 | — |
| Example 6 | 33.2 | 5.1 | 121 | 81.0 | 80.7 | 47.7 | 1.7 | A |
| Example 7 | 14.4 | 4.9 | 95 | 43.4 | 44.5 | 27.3 | 1.6 | A |
| Example 8 | 25.7 | 4.6 | 110 | 38.5 | 39.7 | 28.1 | 1.4 | A |
| Example 9 | 23.4 | 1.0 | 84 | 33.5 | 36.3 | 25.6 | 1.3 | A |
| Example 10 | 25.9 | 1.0 | 97 | 48.3 | 50.1 | 32.9 | 1.5 | A |
| Example 11 | 17.6 | 4.0 | 88 | 32.2 | 33.4 | 22.1 | 1.5 | A |
| Example 12 | 25.0 | 3.8 | 102 | 37.3 | 39.5 | 26.3 | 1.4 | A |

From the above, it is clear that a passivation film superior in passivation effect can be formed using a composition for forming a passivation film according to the invention. Further, it is clear that a composition for forming a passivation film according to the invention is superior in storage stability. Moreover it is clear that a passivation film can be formed in a desired shape according to a simple process by use of a composition for forming a passivation film according to the invention.

The entire contents of the disclosure of Japanese Patent Application No. 2012-001641 are incorporated herein by reference.

All the literature, patent literature, and technical standards cited herein are also herein incorporated by reference to the same extent as provided for specifically and severally with respect to an individual literature, patent literature, and technical standard to the effect that the same should be so incorporated by reference.

1. A composition for forming a passivation film, comprising:
an organic aluminum compound represented by the following General Formula (I); and
a resin: 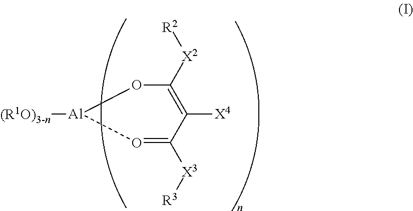
wherein in General Formula (I), R¹'s each independently represent an alkyl group having 1 to 8 carbon atoms; n represents an integer of from 0 to 3; X² and X³ each independently represent an oxygen atom or a methylene group; and R², R³ and R⁴ each independently represent a hydrogen atom or an alkyl group having 1 to 8 carbon atoms.

2. The composition for forming a passivation film according to claim 1, wherein R¹'s in General Formula (I) each independently represent an alkyl group having 1 to 4 carbon atoms.

3. The composition for forming a passivation film according to claim 1, wherein in General Formula (I), n is an integer of from 1 to 3, and R⁴'s each independently represent a hydrogen atom or an alkyl group having 1 to 4 carbon atoms.

4. The composition for forming a passivation film according to claim 1, wherein a content of the resin is from 0.1 mass % to 30 mass %.

5. A semiconductor substrate provided with a passivation film, comprising:
a semiconductor substrate; and
a passivation film which is a heat-treated product of the composition for forming a passivation film according to claim 1 and which is provided on all or a part of a surface of the semiconductor substrate.

6. A method of producing a semiconductor substrate provided with a passivation film, the method comprising:
forming a composition layer using the composition for forming a passivation film according to claim 1 on all or a part of a surface of a semiconductor substrate; and
heat-treating the composition layer to form a passivation film.

7. A photovoltaic cell element, comprising:
a semiconductor substrate having a p-n junction of a p-type layer and an n-type layer,
a passivation film which is a heat-treated product of the composition for forming a passivation film according to claim 1 and is arranged on all or a part of a surface of the semiconductor substrate; and
an electrode arranged on at least one layer selected from the group consisting of the p-type layer and the n-type layer of the semiconductor substrate.

8. A method of producing a photovoltaic cell element, comprising:
forming a composition layer by applying the composition for forming a passivation film according to claim 1 onto a semiconductor substrate, the semiconductor substrate comprising a p-n junction of a p-type layer and an n-type layer and an electrode arranged on one or more layers selected from the group consisting of the p-type layer and the n-type layer, the composition layer being formed on one or both surfaces having the electrode of the semiconductor substrate; and
heat-treating the composition layer to form a passivation film.
